(19) United States
(12) Patent Application Publication
(10) Pub. No.: US 2012/0133419 A1
(43) Pub. Date: May 31, 2012

(54) TRIGGER CIRCUIT AND RECTIFIER, IN PARTICULAR FOR A SELF-POWERED MICROSYSTEM HAVING A PIEZOELECTRIC MICROGENERATOR

(76) Inventors: Alexander Frey, Munchen (DE); Djordje Marinkovic, Munchen (DE)

(21) Appl. No.: 13/389,369

(22) PCT Filed: Jul. 6, 2010
(86) PCT No.: PCT/EP2010/059636

§ 371 Date: Feb. 7, 2012

(30) Foreign Application Priority Data
Aug. 7, 2009 (DE) 10 2009 036.7

(51) Int. Cl. H03K 17/687

(52) U.S. Cl. 327/427

(57) ABSTRACT

For detecting a sufficiently large voltage level and providing sufficient output power, a trigger circuit is provided. A rectifier can also be provided, providing effectively greater output power compared to known solutions at the same input voltage. Two competing field effect transistors are used in the trigger circuit. A field effect transistor connected as a diode is connected in parallel to an active rectifier in the rectifier circuit. The trigger circuit and rectifier are useable in a self-powered microsystem including a piezoelectric microgenerator.

### CROSS REFERENCE TO RELATED APPLICATIONS

This application is the U.S. national stage of International Application No. PCT/EP2010/059636, filed Jul. 6, 2010 and claims the benefit thereof. The International Application claims the benefit of German Application No. 10 2009 036 623.7 filed on Aug. 7, 2009, both applications are incorporated by reference herein in their entirety.

### BACKGROUND

Described below is an electronic device for switching an electric power through to an electric load, with an alternating voltage that is made available first being able to be rectified. A source for an electric power that is made available can be, for example, a microgenerator that provides an alternating voltage by a series-connected capacitor.

A self-powered microsystem contains as a rule one or more microgenerators, a rectifier, an energy-storage element, and one or more sensors. The microsystem usually also contains a d.c./d.c. converter, an RF block, and a plurality of additional circuits. A microgenerator delivers a power in the microwatt or milliwatt range. Capacitors, super-capacitors, or rechargeable batteries can be used as storage elements.

A self-powered system can have the following elements: A charge pump and an oscillator that perform the function of d.c./d.c. converting on a microchip. A passive rectifier charges the energy-storing element which is a capacitor, for example. That circuit block is indispensable during what is termed a start-up phase. However, it causes a disadvantageous voltage drop and operates with poor efficiency. The passive rectifier consequently acts as a bottleneck on the entire system.

A trigger circuit is needed to detect whether the voltage level and the stored energy on the storage capacitor are large enough to be able to activate other, in particular active parts of the system. The monitored voltage level has to satisfy the following two criteria: Firstly, the oscillator and charge pump must be able to operate within the scheduled voltage range, and secondly, there must be enough stored energy on the capacitor to enable the charge pump's start-up phase.

A requirement placed on the trigger circuit is for it to operate on the one hand as a classical start-up circuit—that relates to detecting the supply voltage—and simultaneously as an on/off circuit. Conventional solutions are not possible for microgenerator voltages that are significantly below the CMOS supply level because known circuit blocks such as, for instance, a classical comparator, will not operate owing, for example, to a low supply voltage. Another requirement placed on a trigger circuit is a low power consumption. It has to be low compared with a system power consumption. Another requirement is the switching speed, meaning the time needed by the trigger circuit to activate the rest of the system. That time is to be seen in direct correlation with the energy needed for that operation. The energy may possibly not suffice to support the system's start-up phase if the transition takes too long. The switching time must therefore be as short as possible. Finally, the possibility of setting a voltage threshold for the trigger circuit is desirable. Different microgenerators and system concepts supply different voltage levels. The trigger circuit should have the possibility of establishing appropriate voltage levels through its architecture.

Only relatively simple systems whose architecture is different have hitherto been realized in the microwatt range. The differences are to be found in the type of microgenerator, in its voltage amplitude, and in the kind of rectifier and d.c./d.c. converter. Many systems do not need a start-up circuit because of the large voltage amplitudes at the input. The systems are as a rule in the mesoscopic range and supply powers in the milliwatt range. Other systems use off-chip components, in particular coils, for d.c./d.c. converting, employ passive diodes for start-up operations, and place corresponding requirements on voltage amplitudes at the input, S. Xu et al., Low Frequency Pulsed Resonant Converter for Energy Harvesting, IEEE Transactions on Power Electronics, January 2007, Vol. 22, No. 1, pp. 63-67. Hitherto employed passive rectifiers are based on the one hand on one or more MOSFET diodes having a corresponding voltage drop and operating with poor efficiency. On the other hand, technically complex and expensive solutions have been proposed that are based on a process modification or the programming of floating-gate transistors. A process modification can be based on using low-threshold/zero-threshold transistors that are not standard in CMOS technology. Programming floating-gate transistors requires an additional step and hence entails an extra expense, C. Peters et al., High-bandwidth floating gate CMOS rectifiers with reduced voltage drop, IEEE International Symposium on Circuits and Systems, May 2008, pp. 2598-2601.

### SUMMARY

An aspect is to provide a trigger circuit for detecting a sufficiently large voltage level and for providing sufficient output power, with its being required for the trigger circuit also to operate as an on/off circuit and have a low power consumption and short switching time, and for a switching-voltage threshold to be capable of being variably set. A rectifier can furthermore be provided which with the same output voltage provides effectively more output power than known solutions and so improves rectifier efficiency during a start-up phase. The trigger circuit and rectifier are intended to be capable of being used particularly in a self-powered microsystem having a piezoelectric microgenerator.

According to a first aspect, a source-drain path of a first field-effect transistor of a first type producing a current source is electrically connected in series with a source-drain path of a second field-effect transistor of a second type producing a current source between an input voltage and a third electric voltage, with a first terminal of the first field-effect transistor and a first terminal of the second field-effect transistor being electrically connected to a gate of a third field-effect transistor of the second type producing a switch and the input voltage and an output voltage being electrically applied to a source-drain path of the third field-effect transistor. Operating points of the first and second field-effect transistor are each set such that when the input voltage is below a threshold, one field-effect transistor will in an active range provide a greater current than the other and, vice versa, when the input voltage is above the threshold, with a field-effect transistor being in the active range when its drain-source voltage is greater than a saturation drain-source voltage.

A source-drain path can be referred to also as a channel of a field-effect transistor.

Described below is a novel architecture whose function is to start a system up in an energy-efficient and reliable manner. A first aspect is concerned with a trigger circuit meeting the described object-specific requirements. A second aspect is concerned with a solution going beyond a conventional approach that employs passive rectifying. The aim overall is to provide an interface circuit between an energy generator and a load, which circuit will make it possible to minimize the critical input power for the system's reliable functioning.

A basic idea for a trigger circuit or, as the case may be, start-up circuit calls for realizing a comparator-like behavior for detecting when a voltage threshold is exceeded. The circuit's principal function is achieved by two mutually competing field-effect transistors because a voltage threshold for a system of such kind is in a low voltage range where a comparator design is problematic. The rest of the start-up circuit will enable the voltage threshold to be set and make fast transition phases and low power consumption possible.

Reliable start-up behavior is possible and critical input power by which the system can start up will have been reduced. A smaller input voltage will be required for operating a system. Less power will be consumed. It will be possible to set a voltage threshold. A primary system behavior will not be affected by a start-up circuit.

According to an advantageous embodiment, the first field-effect transistor's operating point can have been set through its being possible for a first capacitor and second capacitor to have been electrically connected in series between the input voltage and third electric voltage and a gate of the first field-effect transistor and a first terminal of a fourth field-effect transistor of the first type producing a current sink can have been electrically connected to the electric connection between the first and second capacitor, with its being possible for a gate of the fourth field-effect transistor to have been electrically connected to a second terminal of the fourth field-effect transistor and to the third electric voltage, and the second field-effect transistor's operating point can have been set through its being possible for a third capacitor to have been electrically connected between a gate of the second field-effect transistor and the third electric voltage and a first terminal of a seventh field-effect transistor of the first type producing a current sink can have been electrically connected to the gate of the second field-effect transistor, with its being possible for a gate of the seventh field-effect transistor to have been electrically connected to a second terminal of the seventh field-effect transistor and the third electric voltage.

According to another advantageous embodiment, the output voltage can have been electrically applied to a gate of a fifth field-effect transistor of the first type producing a switch, the third electric voltage can have been applied to a second terminal of the fifth field-effect transistor, and a first terminal of the fifth field-effect transistor can have been electrically connected to the gate of the third field-effect transistor.

According to another advantageous embodiment, the output voltage can have been electrically applied to a gate of a sixth field-effect transistor of the first type producing a switch, the third electric voltage can have been applied to a second terminal of the sixth field-effect transistor, and a first terminal of the sixth field-effect transistor can have been electrically connected to the gate of the first field-effect transistor.

According to another advantageous embodiment, the third electric voltage can have been electrically applied to a gate of an eighth field-effect transistor of the second type producing a switch, the output voltage can have been electrically applied to a second terminal of the eighth field-effect transistor, and a first terminal of the eighth field-effect transistor can have been electrically connected to the gate of the second field-effect transistor.

According to another advantageous embodiment, the operating point of the first field-effect transistor (M1) can have been set through its being possible for a second terminal of the first field-effect transistor to have been electrically connected to a first terminal of a twelfth field-effect transistor of the first type, for a bulk terminal of the first field-effect transistor to have been electrically connected to the third electric voltage via a bulk terminal of the twelfth field-effect transistor, and for the input voltage to be applied to a gate of the first field-effect transistor, with its being possible for the third electric voltage to be applied to a second terminal of the twelfth field-effect transistor and a gate of the twelfth field-effect transistor to have been electrically connected to a first inverter, and the second field-effect transistor's operating point can have been set through its being possible for the third electric voltage to be applied to a gate of the second field-effect transistor.

According to another advantageous embodiment, a second inverter can have been electrically connected between the first terminals of the first and second field-effect transistor on the one hand and the gate of the third field-effect transistor on the other.

According to another advantageous embodiment, the first inverter can have a thirteenth field-effect transistor of the first type, with its being possible for the third electric voltage to be applied to a second terminal of the thirteenth field-effect transistor, for a first terminal of the thirteenth field-effect transistor to have been electrically connected to a first terminal of a fourteenth field-effect transistor of the second type and to the gate of the twelfth field-effect transistor, and for a gate of the thirteenth field-effect transistor to have been electrically connected to a gate of the fourteenth field-effect transistor and to have been applied to the output voltage, with its being possible for the input voltage to have been applied to a second terminal of the fourteenth field-effect transistor.

According to another advantageous embodiment, the second inverter can have a fifteenth field-effect transistor of the first type, with its being possible for the third electric voltage to have been applied to a second terminal of the fifteenth field-effect transistor, for a first terminal of the fifteenth field-effect transistor to have been electrically connected to a first terminal of a sixteenth field-effect transistor of the second type and to the gate of the third field-effect transistor, and for a gate of the fifteenth field-effect transistor to have been electrically connected to a gate of the sixteenth field-effect transistor and to the first terminals of the first and second field-effect transistor, with its being possible for the input voltage to have been applied to a second terminal of the sixteenth field-effect transistor.

According to another advantageous embodiment, a fourth capacitor can have been electrically connected between the input voltage and third electric voltage.

According to another advantageous embodiment, a source-drain path of a ninth field-effect transistor of the first type producing a diode can have been electrically connected between the input voltage and a fourth electric voltage, with its being possible for a gate of the ninth field-effect transistor to have been electrically connected to a first terminal of the ninth field-effect transistor.

According to another advantageous embodiment, a source-drain path of a tenth field-effect transistor of the second type producing a switch can have been connected electrically in parallel with the source-drain path of the ninth field-effect transistor.

According to another advantageous embodiment, it is possible in the case of a first operational amplifier producing an electronic comparator for the fourth electric voltage to have been applied to a negative input and the input voltage to have been applied to a positive input, and for an output to have been electrically connected to a gate of the tenth field-effect transistor.

According to another advantageous embodiment, the fourth electric voltage and third electric voltage can have been applied to a source-drain path of an eleventh field-effect transistor of the first type producing a switch.

According to another advantageous embodiment, it is possible in the case of a second operational amplifier producing an electronic comparator for the fourth electric voltage to have been applied to a negative input and the third electric voltage to have been applied to a positive input, and for an output to have been electrically connected to a gate of the eleventh field-effect transistor.

According to another advantageous embodiment, the input voltage can in each case be applied to the first and second operational amplifier as a supply voltage.

According to another advantageous embodiment, a microgenerator can provide the fourth electric voltage with reference to the third electric voltage and the output voltage can have been applied to a load requiring to be electrically powered.

According to another advantageous embodiment, the third electric voltage can be chassis. What is meant by “chassis” is ground or zero potential.

According to another advantageous embodiment, the first terminal can be a drain and the second terminal a source of a field-effect transistor.

According to another advantageous embodiment, the first type can be an n-type and the second type a p-type of field-effect transistor.

According to another advantageous embodiment, the field-effect transistors can be metal-oxide semiconductor field-effect transistors.

According to another advantageous embodiment, a device can have the following two states: Blocking state of the source-drain paths of the third, fifth, sixth, and eighth field-effect transistor with the input voltage below the threshold, with the current through a channel of the second field-effect transistor being greater than the current through a channel of the first field-effect transistor; conducting state of the source-drain paths of the third, fifth, sixth, and eighth field-effect transistor with the input voltage above the threshold, meaning the input voltage is above a threshold, with the current through a channel of the first field-effect transistor being greater than the current through a channel of the second field-effect transistor.

According to another advantageous embodiment, an alternative device can have the following two states: Blocking state of the source-drain path of the third field-effect transistor with the input voltage below the threshold, with the current through a channel of the first field-effect transistor being greater than the current through a channel of the second field-effect transistor; or conducting state of the source-drain path of the third field-effect transistor with the input voltage above the threshold, with the current through a channel of the second field-effect transistor being greater than the current through a channel of the first field-effect transistor.

According to another advantageous embodiment, the threshold can be set by a width/length ratio between the first and second field-effect transistor.

According to another advantageous embodiment, the threshold can be set by a ratio between the first and second capacitor and/or by the third capacitor.

According to another advantageous embodiment, a device can switch as follows: The first operational amplifier compares the magnitude of the fourth electric voltage with that of the electric input voltage and switches the tenth field-effect transistor into the conducting state if the fourth electric voltage is greater than the input voltage.

According to another advantageous embodiment, the second operational amplifier can compare the magnitude of the fourth electric voltage with that of the third electric voltage and switch the eleventh field-effect transistor into the conducting state if the fourth electric voltage is smaller than the third electric voltage.

### BRIEF DESCRIPTION OF THE DRAWINGS

These and other aspects and advantages will become more apparent and more readily appreciated from the following description of exemplary embodiments, taken in conjunction with the accompanying drawings of which:

FIG. 1 is a circuit diagram of a first exemplary embodiment of a circuit;

FIG. 2 is a graph of the characteristic curves of the first and second field-effect transistors in FIG. 1;

FIG. 3 is a circuit diagram of an exemplary embodiment of a rectifier circuit;

FIG. 4 is a block diagram of an input stage of a self-powered system;

FIG. 5 is a block diagram of a self-powered system;

FIG. 6 is a circuit diagram of a second exemplary embodiment of a circuit.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

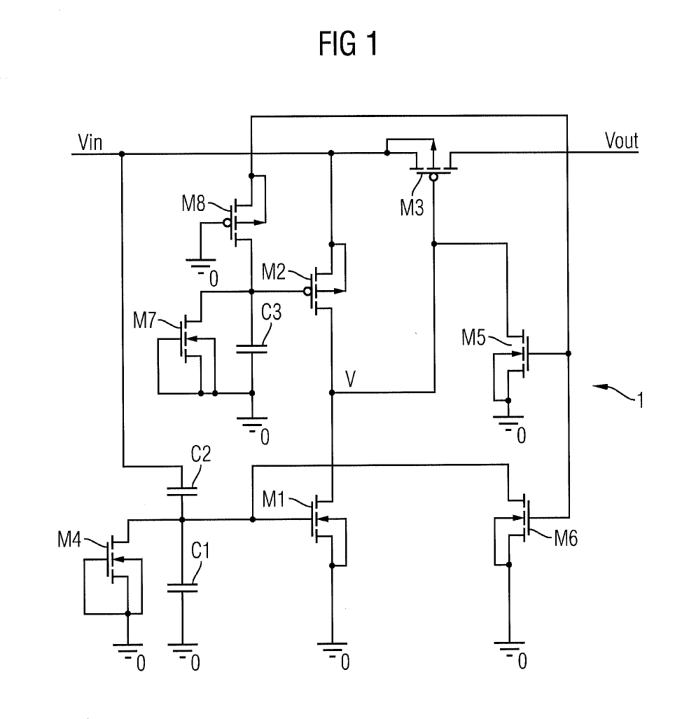

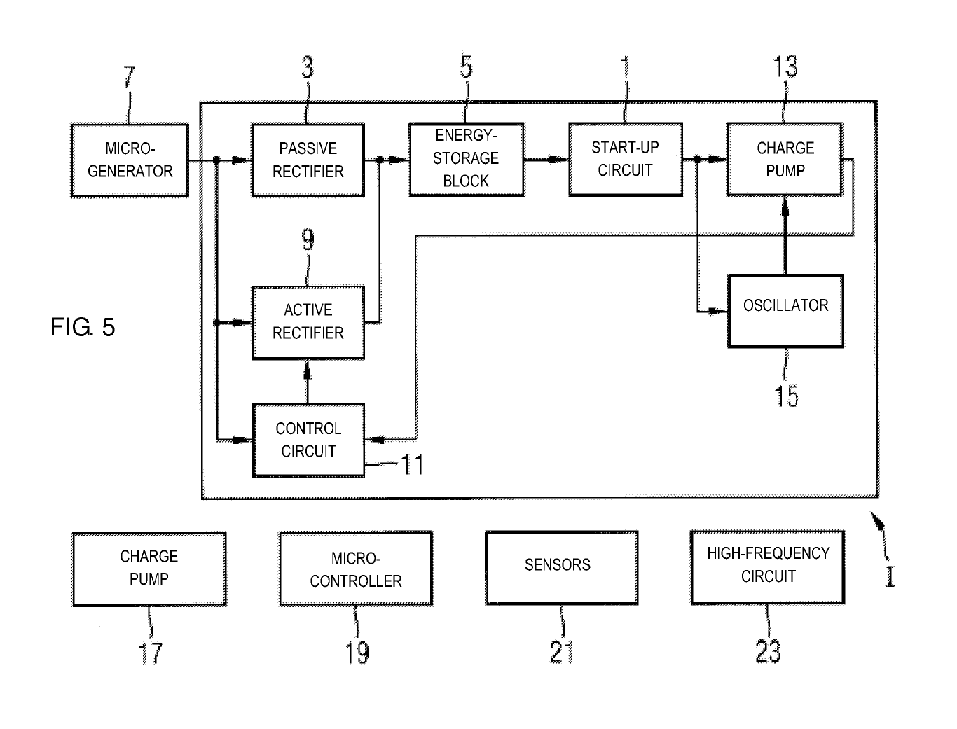

FIG. 1 shows a first exemplary embodiment of a device, in particular a trigger circuit 1. Reference numeral 1 identifies a trigger circuit 1 as shown in FIG. 5 as block 1. A source-drain path of a first field-effect transistor M1 of a first type producing a current source is electrically connected in series with a source-drain path of a second field-effect transistor M2 of a second type producing a current source between an input voltage Vin and a third electric voltage, with a first terminal of first field-effect transistor M1 and a first terminal of second field-effect transistor M2 being electrically connected to a gate of a third field-effect transistor M3 of the second type producing a switch and input voltage Vin and output voltage Vout being electrically applied to a source-drain path of third field-effect transistor M3, with the operating points of first and second field-effect transistor M1, M2 each being set such that when input voltage Vin is below a threshold, one field-effect transistor M2; M1 will in an active range provide a greater current than the other and vice versa M1; M2 when input voltage Vin is above the threshold, with a field-effect transistor being in the active range when its drain-source voltage is greater than a saturation drain-source voltage. The operating point of first field-effect transistor M1 has been set through a first capacitor C and second capacitor C2 having been electrically connected in series between input voltage Vin and the third electric voltage and a gate of first field-effect transistor M1 and a first terminal of a fourth field-effect transistor M4 of the first type producing a current sink having been electrically connected to the electric connection between first and second capacitor C1, C2, with a gate of the fourth field-effect transistor M4 having been electrically connected to a second terminal of fourth field-effect transistor M4 and to the third electric voltage, and the operating point of second field-effect transistor M2 has been set through a third capacitor C3 having been electrically connected between a gate of second field-effect transistor M2 and the third electric voltage and a first terminal of a seventh field-effect transistor M7 of the first type producing a current sink having been electrically connected to the gate of second field-effect transistor M2, with a gate of seventh field-effect transistor M7 having been electrically connected to a second terminal of seventh field-effect transistor M7 and the third electric voltage. Output voltage Vout has been electrically applied to a gate of a fifth field-effect transistor M5 of the first type producing a switch, the third electric voltage has been applied to a second terminal of fifth field-effect transistor M5, and a first terminal of fifth field-effect transistor M5 has been electrically connected to the gate of third field-effect transistor M3. Output voltage Vout has been electrically applied to a gate of a sixth field-effect transistor (M6) of the first type producing a switch, the third electric voltage has been applied to a second terminal of sixth field-effect transistor M6, and a first terminal of sixth field-effect transistor M6 has been electrically connected to the gate of first field-effect transistor M1. The third electric voltage has been electrically applied to a gate of an eighth field-effect transistor M8 of the second type producing a switch, output voltage Vout has been electrically applied to a second terminal of eighth field-effect transistor M8, and a first terminal of eighth field-effect transistor M8 has been electrically connected to the gate of second field-effect transistor M2.

FIG. 1 shows a realization of a basic idea for the trigger circuit. Transistors M1 and M2 regulate voltage V and thereby control transistor M3 which has the function of a switch. Capacitors C1 and C2 serve together with transistor M4 to set the operating point of transistor M1. Capacitor C3 and the other transistor M7 serve to set the operating point of transistor M2 or, as the case may be, bias it. Transistors M6, M8 and capacitor C3 will block transistors M1 and M2 if output voltage Vout is sufficiently high. Biasing of transistor M3 will then be performed by transistor M5.

Transistors M1 and M2 are the circuit's core. They compete with each other, meaning that voltage V must meet the criteria of both characteristic curves. Generally, when the two transistors are connected as shown in FIG. 1 and if the same current is flowing through them, their behavior will be as follows: The transistor potentially capable of supplying the greater current owing to its larger dimensions and/or a gate-source voltage /Vgs/ of higher value will have to reduce its current by a smaller drain-source voltage Vds. The idea is that transistor M2 is the “stronger” transistor during a first phase, specifically if input voltage Vin is even smaller than the voltage threshold, and transistor M1 in the other, second phase. With appropriate dimensioning, the crossover event determining which transistor is the “stronger” takes place the instant input voltage Vin reaches the desired voltage threshold. V drops and transistor M3 conducts at that instant.

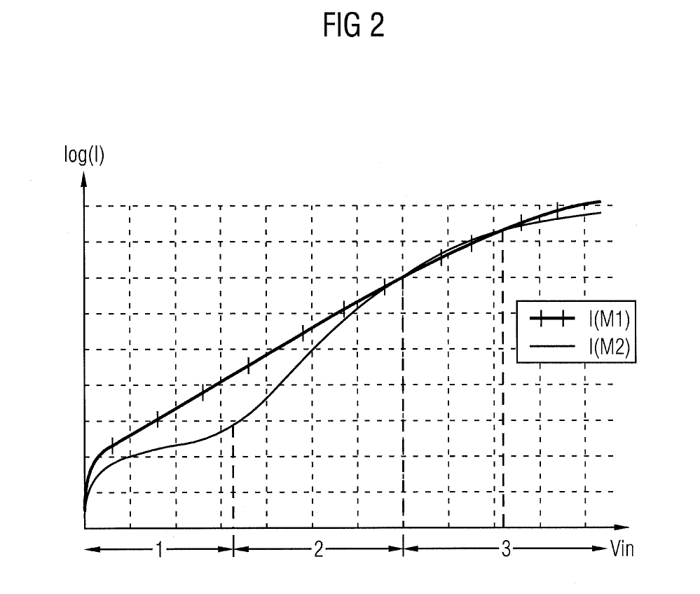

FIG. 2 shows the current of first transistor M1 and second transistor M2 as a function of input voltage Vin, specifically for the case when drain-source voltage Vds is the same as input voltage Vin. Vin here plays the role of the supply voltage. The curve with the vertical strokes corresponds to first field-effect transistor M1 and the other curve corresponds to second field-effect transistor M2. The curves' different shape enables them to be able to intersect at two points. The first intersection is located at the transition from range 2 to range 3 and the second intersection is located to the right thereof in range 3 of input voltage Vin. The difference between the two characteristic curves is due to different dimensioning and biasing or, as the case may be, operating-point settings. Although dimensioned as being greater, first field-effect transistor M1 receives only a part of input voltage Vin, specifically via the voltage divider of first capacitor C1 and second capacitor C2. Second field-effect transistor M2 is dimensioned such that the bulk current will dominate for the smaller values of input voltage Vin. That is range 1 in FIG. 2. The sub-threshold current will gradually come to dominate at somewhat greater values of input voltage Vin. That is range 2 in FIG. 2. Input voltage Vin will finally become greater than the cut-off voltage of second field-effect transistor M2 and transistor M2 will operate in saturation. That is range 3 in FIG. 2. First field-effect transistor M1 is dimensioned as being greater, at least its width/length ratio is greater than that of second field-effect transistor M2. Its characteristic curve is consequently linear for the most part, meaning that the sub-threshold current will dominate, with the graph here being semilogarithmically scaled. The setting of the voltage threshold, meaning the intersection on the right, can be provided by the transistors' width/length ratio. The level of the characteristic curve will be changed thereby. Another possibility for setting the voltage threshold is offered by providing the voltage-divider ratio between first capacitor C1 and second capacitor C2. Sixth field-effect transistor M6 and eighth field-effect transistor M8 will turn first transistor M1 and second transistor M2 off if input voltage Vin is sufficiently large and third field-effect transistor M3 is conducting. Biasing of third field-effect transistor M3 will then be performed by fifth field-effect transistor M5. Of the three field-effect transistors M1, M2, and M3 consequently only third field-effect transistor M3 will remain as the sole transistor that is conducting, which in the final analysis results in low losses.

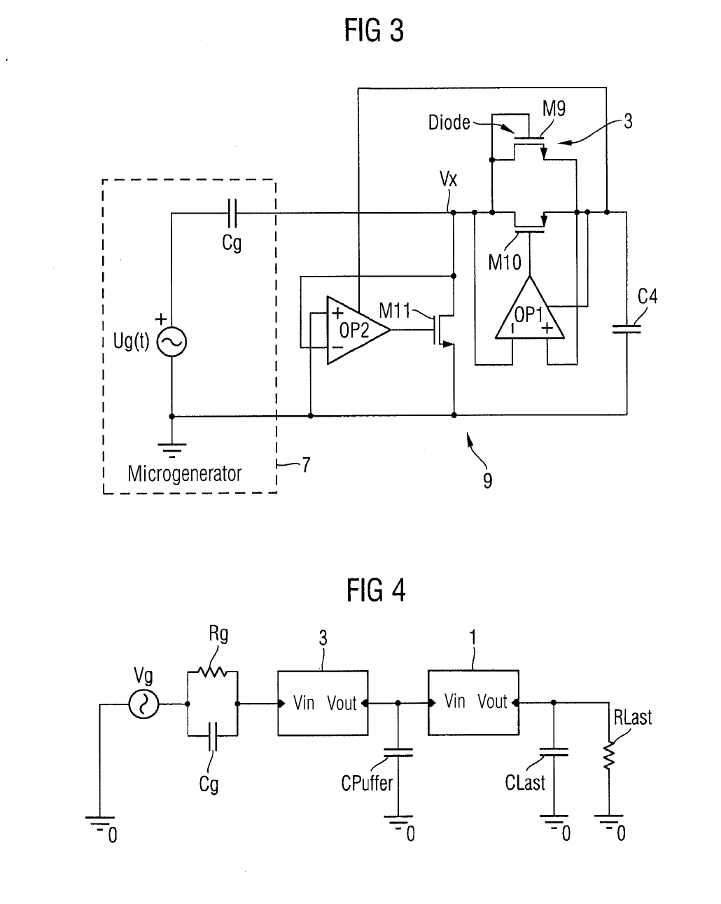

FIG. 3 shows an exemplary embodiment of a rectifier circuit. A rectifier circuit of such kind can be electrically connected upstream of a trigger circuit. For another aspect, specifically for a rectifying operation performed while a system is being started up, a novel circuit combines two principles of rectifying. Specifically, a metal-oxide semiconductor transistor operating like a diode is connected in parallel with an active rectifier that uses the rectifier circuit's one currently available output voltage as a supply. Because the output voltage rises during a start-up phase starting from zero, the active rectifier will start operating the instant a voltage level is sufficient. Although the active rectifier does not operate at its full efficiency to begin with, it can still supply additional output power. Compared with a purely passive, classical solution the proposed rectifier circuit will in that way be able to supply significantly more output power with the same output voltage. Rectifier efficiency during a start-up phase will be improved thereby.

Reference numeral 3 identifies a passive rectifier as shown in FIG. 5 as block 3. Reference numeral 9 identifies an active rectifier as shown in FIG. 5 as block 9. Reference numeral 7 identifies the microgenerator. That is also shown in FIG. 5 as block 7.

According to FIG. 3, as passive rectifier 3 a ninth field-effect transistor M9 connected as a diode is electrically connected in parallel with an active rectifier circuit 9. The elements of the active rectifier circuit are a tenth field-effect transistor M10 which can be switched by a first operational amplifier OP1 and an eleventh field-effect transistor M11 which can be switched by a second operational amplifier OP2. A buffer capacitor C4 has been electrically connected between an output of tenth field-effect transistor M10 and a third electric voltage. The principle of active rectifying is applied to a microgenerator having a capacitive output as shown in FIG. 3. A microgenerator of such kind is shown on the left-hand side in FIG. 3 inside the block having a dashed outline. The capacitive output of the microgenerator is shown as capacitor Cg. A simplified model of a piezoelectric microgenerator is employed here having a voltage source Ug (t) and a serial output capacitor Cg. The voltage source can make various wave shapes available depending specifically on the microgenerator's design. The value of Cg is likewise design-dependent. Cg is in the order of magnitude of several tens of nF. Buffer capacitor C4 has a value considerably greater than Cg. That justifies an approximation of C4 as a direct-current source. Two switches M10 and M11 have internal resistance values R and are realized as MOSFET field-effect transistors. Tenth field-effect transistor M10 operates as a first switch S1 and eleventh field-effect transistor M11 operates as a second switch S2. The basic idea behind active rectifying is similar to the idea employed in any circuit having a switched capacitor: Charge transference by capacitors and switches, with a suitable time characteristic providing a required charge flow. Incorporated microgenerator capacitor Cg is used here instead of known capacitor implementations, with the principle being the same. The active rectifier operates in four phases in the stationary system. Switch S1 is driven by operational amplifier OP1 and is active when a fourth voltage Vx is greater than a voltage on capacitor C4. Switch S2 is controlled by operational amplifier OP2 and is active when the fourth voltage Vx is less than 0. The four phases of operation can be described as follows:

Phase 1: Switches S1 and S2 are open in phase 1. The generator voltage rises from an initial 0 volt. Fourth voltage Vx directly follows generator voltage Ug because the voltage over capacitor Cg remains at 0. Both switches S1 and S2 are inactive during that phase so that node Vx is flowing and there is no path for charging or discharging capacitor Cg.

Phase 2: Switch S1 is closed and switch S2 is open. This phase begins when fourth voltage Vx reaches the value of the voltage on capacitor C4, which is input voltage Vin, with a signal of operational amplifier OP1 activating switch S1. The voltage on capacitor Cg rises during this phase, during which Vx is constant and the same as Vin, so that a current i (t) flows through the circuit. The current puts charge through C4 so that an output power is made available. It is only in that phase that buffer capacitor C4 will receive charge.

Phase 3: Switch S1 and switch S2 are open. This phase begins when the current through the circuit drops to 0 and changes its direction. Switch S1 is deactivated at that instant so that node Vx flows once more. Capacitor Cg remains charged as there is no current path; its voltage remains constant and node Vx follows source voltage Ug (t) with an offset due to the value of the voltage on capacitor Cg at an instant t2 which is not 0V.

Phase 4: Switch S1 is open and switch S2 is closed. Switch S2 will have been activated and phase 4 will begin when fourth voltage Vx drops to 0 and becomes negative. Fourth voltage Vx will then be forced to ground, the voltage on capacitor Cg will drop, and current i (t) will flow, with capacitor Cg being discharged. Voltage Ug will rise once more at that instant and current i (t) will change its direction, which will be registered, and switch S2 will consequently be deactivated. The 4-phase cycle will start once more at that instant.

The final phase is necessary because capacitor Cg would stay charged without phase 4. That would produce an offset between Ug and fourth voltage Vx so that the peak voltage for fourth voltage Vx would only be the voltage on capacitor C4, which would not suffice to close switch S1 and provide the current flow. The generator would operate all the time in an open-circuit operating mode. Phase 4 provides for discharging of capacitor Cg, and specifically for effective short-circuiting of the microgenerator's electrodes so that capacitor Cg can be charged once more in phase 2, which provides for charge transporting to the output. The amount of charge transferred to the output is determined by the maximum voltage on capacitor Cg.

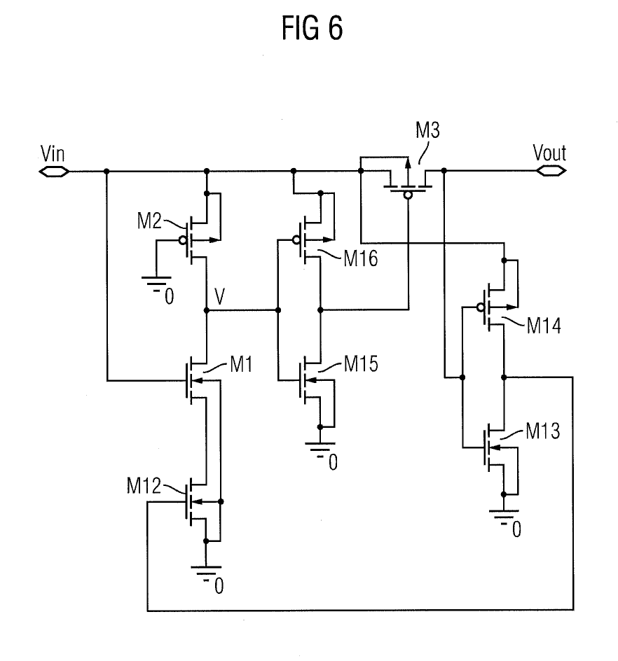

FIG. 4 shows an exemplary embodiment of an input stage of a self-powered microsystem. Reliable start-up is made possible by a trigger circuit 1 that can be referred to also as a start-up circuit. The trigger circuit 1 corresponds to a device as shown in FIG. 1 or FIG. 6. The start-up circuit monitors the voltage on capacitor C_{Puffer}, and if the voltage is greater than the voltage threshold specified for the system, start-up circuit 1 will activate the rest of the system shown in FIG. 4 as C_{Last} and R_{Last}. Start-up circuit 1 will consume negligible power as of that instant so that all the power supplied by a passive rectifier 3 will continue being transferred to the load. In FIG. 3, ninth field-effect transistor M9 constitutes a passive rectifier 3. FIG. 4 is a block diagram of an input stage of a self-powered system. Voltage source Vg and an impedance block between voltage source Vg and passive rectifier 3 constitute a microgenerator.

FIG. 5 is a block diagram of a self-powered system. An energy-storage block 5 between a passive rectifier 3 and a start-up circuit 1 constitutes a capacitor or rechargeable battery. One aspect is concerned with starting up a self-powered microsystem as shown in FIG. 5. A microgenerator 7 drives a power-management circuit I. Microgenerator 7 supplies a signal that is rectified by a passive rectifier 3 and active rectifier 9 and an associated control circuit 11. The rectified signal is fed to an energy-storage block 5 that drives a trigger circuit 1 or, as the case may be, start-up circuit 1. Trigger circuit 1 supplies a charge pump 13 and oscillator 15 with electric power. Charge pump 13 likewise drives control circuit 11. Active rectifier 9 is driven by control circuit 11. A second charge pump 17, a microcontroller 19, sensors 21, and a high-frequency circuit RF 23 can be driven by power-management circuit I. Accordingly, a trigger circuit as shown in FIG. 1 or FIG. 6 corresponds to trigger circuit 1. Connected upstream thereof is a combination of a passive rectifier 3 and active rectifier 9 corresponding to FIG. 3. Capacitor C4 as shown in FIG. 3 can therein be energy-storage block 5 as shown in FIG. 5. A microgenerator 7 is also shown in FIG. 3 as a block having a dashed outline.

FIG. 6 shows a second exemplary embodiment of an inventive trigger circuit 1 or start-up circuit or start-up-phase circuit. A source-drain path of a first field-effect transistor Ml of a first type producing a current source is electrically connected in series with a source-drain path of a second field-effect transistor M2 of a second type producing a current source between an input voltage Vin and a third electric voltage, with a first terminal of first field-effect transistor Ml and a first terminal of second field-effect transistor M2 being electrically connected to a gate of a third field-effect transistor M3 of the second type producing a switch and input voltage Vin and an output voltage Vout being electrically applied to a source-drain path of third field-effect transistor M3, with the operating points of first and second field-effect transistor M1, M2 each being set such that when input voltage Vin is below a threshold, one field-effect transistor M2; M1 will in an active range provide a greater current than the other and vice versa M1; M2 when input voltage Vin is above the threshold, with a field-effect transistor being in the active range when its drain-source voltage is greater than a saturation drain-source voltage. The operating point of first field-effect transistor M1 has been set through a second terminal of the first field-effect transistor M1 having been electrically connected to a first terminal of a twelfth field-effect transistor M12 of the first type producing a switch, a bulk terminal of the first field-effect transistor M1 having been electrically connected to the third electric voltage via a bulk terminal of the twelfth field-effect transistor M12, and input voltage Vin being applied to a gate of first field-effect transistor M1, with the third electric voltage being applied to a second terminal of twelfth field-effect transistor M12 and a gate of twelfth field-effect transistor M12 having been electrically connected to a first inverter INV1, and with the operating point of second field-effect transistor M2 being set such that the third electric voltage is applied to a gate of second field-effect transistor M2. A second inverter has been electrically connected between the first terminals of first and second field-effect transistor M1, M2 and the gate of third field-effect transistor M3. First inverter INV1 has a thirteenth field-effect transistor M13 of the first type, with the third electric voltage having been applied to a second terminal of thirteenth field-effect transistor M13, a first terminal of thirteenth field-effect transistor M13 has been electrically connected to a first terminal of a fourteenth field-effect transistor M14 of the second type and to the gate of twelfth field-effect transistor M12 and a gate of thirteenth field-effect transistor M13 has been electrically connected to a gate of fourteenth field-effect transistor M14 and applied to output voltage Vout, with input voltage Vin having been applied to a second terminal of fourteenth field-effect transistor M14. Second inverter INV2 has a fifteenth field-effect transistor M15 of the first type, with the third electric voltage having been applied to a second terminal of fifteenth field-effect transistor M15, a first terminal of fifteenth field-effect transistor M15 having been electrically connected to a first terminal of a sixteenth field-effect transistor M16 of the second type and to the gate of third field-effect transistor M3, and a gate of fifteenth field-effect transistor M15 having been electrically connected to a gate of sixteenth field-effect transistor M16 and to the first terminals of first and second field-effect transistor M1, M2, with the input voltage (Vin) having been applied to a second terminal of sixteenth field-effect transistor M16.

The operation of trigger circuit as shown in FIG. 6 can be described as follows. As Vin rises starting from 0V, the voltage at the gate of twelfth field-effect transistor M12 will follow input voltage Vin because third field-effect transistor M3 is not active and output voltage Vout is 0V. The voltage V at the first terminal (in this case, drain) of first and second field-effect transistor M1 and M2 will likewise follow input voltage Vin. Twelfth field-effect transistor M12 will turn on when input voltage Vin reaches the value of an NMOS threshold voltage Vthn and apply the source of first field-effect transistor M1 to the third voltage (in this case, ground). Second field-effect transistor M2 operates in the sub-threshold range (Vthp>Vthn) and the first field-effect transistor in triode mode, which will pull the voltage V to the third voltage. The second field-effect transistor will go into saturation mode when input voltage Vin reaches the value Vthp. Second field-effect transistor M2 will become “stronger” than first field-effect transistor M1 at a certain value for Vin so that the voltage V will be pulled up and triode mode will commence, whereas first field-effect transistor M1 will go into saturation mode. Second inverter INV2 will at that instant turn on third field-effect transistor M3 that operates as a serial switch between the input and output. The gate voltage of twelfth field-effect transistor M12 will turn M12 off when Vout reaches a high value, which will prevent direct currents from flowing vertically through second, first, and twelfth field-effect transistor M2, M1, and M12. The gate voltage of twelfth field-effect transistor M12 furthermore has the additional function of providing a hysteresis characteristic when input voltage Vin drops. The correct dimensioning of M1 and M2 is critical for achieving the required switching voltage, which allows a bandwidth as a result of variations. That circuit will consume negligible power in stationary mode and only a multiple of nW in switching mode.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-27. (canceled)

28. A device receiving an input voltage and producing an output voltage, comprising:
first and second field-effect transistors of first and second types providing first and second current sources having first and second source-drain paths, respectively, electrically connected in series at a common terminal, the second field-effect transistor providing the second current source between the input voltage and a reference voltage; and
a third field-effect transistor of the second type providing a first switch, having a gate electrically connected to the common terminal of the first and second field-effect transistors and a third source-drain path between the input voltage and the output voltage,
the first and second field-effect transistors having operating points set such that when the input voltage is below a threshold, one of the first and second field-effect transistors is in an active range with a drain-source voltage greater than a saturation drain-source voltage and provides a greater current than the other of the first and second field-effect transistors and when the input voltage is above the threshold provides a lesser current than the other of the first and second field-effect transistors.

29. The device as claimed in claim 28,
wherein each of the first and second field-effect transistors has a gate, and
wherein the device further comprises:
first and second capacitors electrically connected at a connection point and in series between the input voltage and a reference voltage, the connection point of the first and second capacitors electrically connected to the gate of the first field-effect transistor to set the operating point thereof;
fourth and fifth field-effect transistors of the first type, each having a gate and providing a current sink, the fourth field-effect transistor having a first terminal electrically connected to the connection point between the first and second capacitors and a second terminal electrically connected to the gate of fourth field-effect transistor and to the reference voltage, and the fifth field-effect transistor having a first terminal electrically connected to the gate of the second field-effect transistor and a second terminal electrically connected to the gate of the fifth field-effect transistor and to the reference voltage; and
a third capacitor connected between the gate of the second field-effect transistor and the reference voltage to set the operating point of the second field-effect transistor.

30. The device as claimed in claim 29, further comprising a sixth field-effect transistor of the first type, providing a second switch and having a gate electrically connected to the output voltage, a first terminal electrically connected to the gate of the third field-effect transistor and a second terminal electrically connected to the reference voltage.

31. The device as claimed in claim 30, further comprising a seventh field-effect transistor of the first type, providing a third switch and having a gate electrically connected to the output voltage, a first terminal electrically connected to the gate of the first field-effect transistor and a second terminal electrically connected to the reference voltage.

32. The device as claimed in claim 31, further comprising an eighth field-effect transistor of the second type, providing a fourth switch and having a gate electrically connected to the reference voltage, a first terminal electrically connected to the gate of the second field-effect transistor and a second terminal electrically connected to the output voltage.

33. The device as claimed in claim 28,
wherein the first field-effect transistor has a bulk terminal and has a gate electrically connected to the input voltage,
wherein the second field-effect transistor has a gate electrically connected to a reference voltage to set the operating point of the second field-effect transistor, and
wherein the device further comprises:
a first inverter; and
a fourth field-effect transistor of the first type, providing a second switch to set the operating point of the first field-effect transistor, having a bulk terminal electrically connecting the bulk terminal of the first field-effect transistor to the reference voltage, a gate connected to the first inverter, and a second terminal electrically connected to the reference voltage.

34. The device as claimed in claim 33, wherein the first inverter comprises:
a fifth field-effect transistor of the first type, having a first terminal electrically connected to the gate of the fourth field-effect transistor, a second terminal electrically connected to the reference voltage, and a gate electrically connected to the output voltage; and
a sixth field-effect transistor of the second type having a first terminal electrically connected to the gate of the fourth field-effect transistor and to the first terminal of the fifth field-effect transistor, a second terminal electrically connected to the input voltage, and a gate electrically connected to the output voltage and to the gate of the fifth field-effect transistor.

35. The device as claimed in claim 33, further comprising a second inverter electrically connected between the first terminals of the first and second field-effect transistor and the gate of the third field-effect transistor.

36. The device as claimed in claim 35, wherein the second inverter comprises:
a fifth field-effect transistor of the first type, having a first terminal electrically connected to the gate of the third field-effect transistor, a second terminal electrically connected to the reference voltage, and a gate electrically connected to the common terminal of the first and second field-effect transistors; and
a sixth field-effect transistor of the second type having a first terminal electrically connected to the gate of the third field-effect transistor and to the first terminal of the fifth field-effect transistor, a second terminal electrically connected to the input voltage, and a gate electrically connected to the common terminal of the first and second field-effect transistors and to the gate of the fifth field-effect transistor.

37. The device as claimed in claim 28, further comprising a capacitor electrically connected between the input voltage and the reference voltage.

38. The device as claimed in claim 37, further comprising a fourth field-effect transistor of the first type providing a diode, having a source-drain path electrically connected between the input voltage and an intermediate voltage, having a first terminal and a gate electrically connected to each other.

39. The device as claimed in claim 38, further comprising a fifth field-effect transistor of the second type providing a second switch, having a gate and having a source-drain path electrically connected in parallel with the source-drain path of the fourth field-effect transistor.

40. The device as claimed in claim 39, further comprising a first operational amplifier providing a first electronic comparator, having a negative input electrically connected to receive the intermediate voltage, a positive input electrically connected to receive the input voltage, and an output electrically connected to the gate of the fifth field-effect transistor.

41. The device as claimed in claim 40, further comprising a sixth field-effect transistor of the first type providing a switch, having a source-drain path electrically connected between the intermediate voltage and the reference voltage.

42. The device as claimed in claim 41, further comprising a second operational amplifier providing a second electronic comparator, having a negative input electrically connected to receive the intermediate voltage, a positive input electrically connected to receive the reference voltage, and an output electrically connected to the gate of the sixth field-effect transistor.

43. The device as claimed in claim 42, wherein the input voltage is applied to each of the first and second operational amplifiers as a supply voltage.

44. The device as claimed in claim 43,
wherein the output voltage is applied to a load to supply electrical power, and
wherein said device further comprises a microgenerator providing the intermediate voltage relative to the reference voltage.

45. The device as claimed in claim 44, further comprising a chassis providing the reference voltage.

46. The device as claimed in claim 45, wherein in each case the first terminal is a drain and the second terminal is a source thereof.

47. The device as claimed in claim 46, wherein the first type is an n-type and the second type is a p-type.

48. The device as claimed in claim 47, wherein the field-effect transistors are metal-oxide semiconductor field-effect transistors.

49. A method for switching a device as claimed in claim 32, comprising:
initiating one of
a blocking state of the source-drain paths of the third, sixth, seventh and eighth field-effect transistors with the input voltage below the threshold and a first current through a first channel of the first field-effect transistor being smaller than a second current through a second channel of the second field-effect transistor, and
a conducting state of the source-drain paths of the third, sixth, seventh and eighth field-effect transistors with the input voltage above the threshold and the first current through the first channel of the first field-effect transistor being greater than the second current through the second channel of the second field-effect transistor.

50. The method as claimed in claim 49, wherein the threshold is set by width/length ratios of the first and second field-effect transistors.

51. The method for switching a device as claimed in claim 36, comprising:
initiating one of
a blocking state of the source-drain path of the third field-effect transistor with the input voltage below the threshold and a first current through a first channel of the first field-effect transistor being greater than a second current through a second channel of the second field-effect transistor, and
a conducting state of the source-drain path of the third field-effect transistor with the input voltage above the threshold and the second current through a second channel of the second field-effect transistor being greater than the first current through the first channel of the first field-effect transistor.

52. The method as claimed in claim 51, wherein the threshold is set by a ratio of the first capacitor to the second capacitor and by the third capacitor.

53. A method for switching a device as claimed in claim 40, wherein the first operational amplifier compares magnitudes of the intermediate voltage and the input voltage and switches the fifth field-effect transistor into a conducting state if the intermediate voltage is greater than the input voltage.

54. A method for switching a device as claimed in claim 42, wherein the second operational amplifier compares magnitudes of the intermediate voltage and the reference voltage and switches the sixth field-effect transistor into a conducting state if the intermediate voltage is smaller than the reference voltage.
